(19) United States
(12) Patent Application Publication
(10) Pub. No.: US 2026/0190469 A1
(43) Pub. Date: Jul. 2, 2026

(54) MULTIPLE DIFFUSIONS FOR MULTI-HEIGHT STANDARD CELLS

(71) Applicant: Intel Corporation, Santa Clara, CA (US)

(72) Inventors: Andy Chih-Hung WEI, Yamhill, OR (US); Everardo FLORES, Penryn, CA (US); Han-Chi LIN, Taichung City (TW)

(21) Appl. No.: 19/002,849

(22) Filed: Dec. 27, 2024

(51) Int. Cl. H10D 84/85

(52) U.S. Cl. CPC H10D 84/851

(57) ABSTRACT

A device including a multi-height cell having a plurality of diffusion areas, each diffusion area having a same length that extends along a horizontal direction of the multi-height cell, every two adjacent diffusion areas of the plurality of diffusion areas separated by a spacing, wherein the spacing extends along in a vertical direction of the multi-height cell; a gate disposed continuously over a central portion of the plurality of diffusion areas, the gate extends along in the vertical direction of the multi-height cell; a source contact disposed continuously over a first portion of the plurality of diffusion areas, the source contact extends along in the vertical direction of the multi-height cell; and a drain contact disposed continuously over a second portion of the plurality of diffusion areas, the drain contact extends along in the vertical direction of the multi-height cell.

### BACKGROUND

A traditional standard cell library includes various functional cells (e.g., logic cells) with the same height and the functional cells can be arranged into rows. A more advanced standard cell library includes functional cells with different heights. With mixed cell heights, simple cells (e.g., inverters) may be implemented as single row height cells and complex cells (e.g., flip flops) may be implemented as multiple row height cells. With mixed cell heights, there are also multiple ways of configuring the driving strength of a functional cell. For example, multiple transistors (e.g., cells) may be connected in parallel to increase the driving current. Alternatively, a width-to-length (e.g., W/L) ratio of a transistor may be increased to increase the driving current. To increase the width W of a transistor, a large (i.e., tall) diffusion area is needed. That is, a single cell having multiple row height may be used so there is enough cell height to fit in a large diffusion.

The use of mixed cell heights introduces complexities in providing reliable cells of different sizes. Therefore, there exists a need to provide improved driving current in multi-height standard cells while still supporting single row height standard cells.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects will be better understood by one of ordinary skill in the art from the following detailed description and in conjunction with the drawings, in which:

FIGS. 1A-1C illustrate cross-sectional views of a small width diffusion area and a large width diffusion area for a channel area of a nanosheet transistor structure related to a nanosheet release process;

FIGS. 2A-2C illustrate cross-sectional views of a small width diffusion area and a large width diffusion area for a source and/or drain area of a nanosheet transistor structure related to a cavity etch and epitaxial layer growth process;

FIG. 3A is a schematic layout showing multiple inverter cells connected in parallel in a single row;

FIG. 3B is a schematic layout showing a double row height inverter cell;

FIG. 4A is schematic layout showing a multi-height cell having large diffusion areas;

FIGS. 4B-4C are schematic layouts showing a multi-height cell having multiple cell diffusion areas according to various non-limiting aspects described herein;

FIGS. 5A-5C are schematic diagrams showing equivalent circuits corresponding to the schematic layouts of FIGS. 4A-4C, respectively;

FIG. 6A is a schematic layout showing a multi-height cell having a single diffusion area and FIG. 6B is a cross-sectional view of the diffusion area thereof;

FIG. 7A is a schematic layout showing a multi-height cell having a two diffusion areas according to various non-limiting aspects described herein and FIG. 7B is a cross-sectional view of the two diffusion areas thereof;

FIGS. 8A-8B are schematic layouts showing a multi-height cell having a different number of diffusion areas according to various non-limiting aspects described herein; and

FIG. 9 is schematic layout showing a portion of a single height cell of a multi-height cell having multiple diffusion areas according to various non-limiting aspects described herein.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [. . . ], etc.). The term “a plurality” may be understood to include a numerical quantity greater than or equal to two (e.g., two, three, four, five, [. . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

As used herein, the term “connect/connected/connection” may refer to a wired or wireless communication link formed between electronic devices that enables data transmission.

Multi-height standard cells get their performance benefit from large diffusion areas. The performance benefit includes a high drive current with low parasitic capacitance as compared to single height cells with multiple legs. However, the maximum size of a nanosheet diffusion area is limited by etch selectivity of silicon germanium (SiGe) relative to silicon (Si), relative to the minimum sized diffusion area in the technology. Similarly, as the nanosheet diffusion area increases so does the difference in epitaxial growth between the large diffusion areas and the smaller diffusion areas. Epitaxial growth is inversely proportional to a size of the diffusion area. For the same process, a thickness of the epitaxial growth on a larger diffusion area is less than a thickness of the epitaxial growth on a smaller diffusion area. Thus, a difference between these two thicknesses increases as there is a greater difference between a width of larger diffusion area and a width of the smaller diffusion area. While these issues can be overcome with extra masks, extra etches, extra epi steps, it is not desirable due to extra cost, complexity, and yield risk.

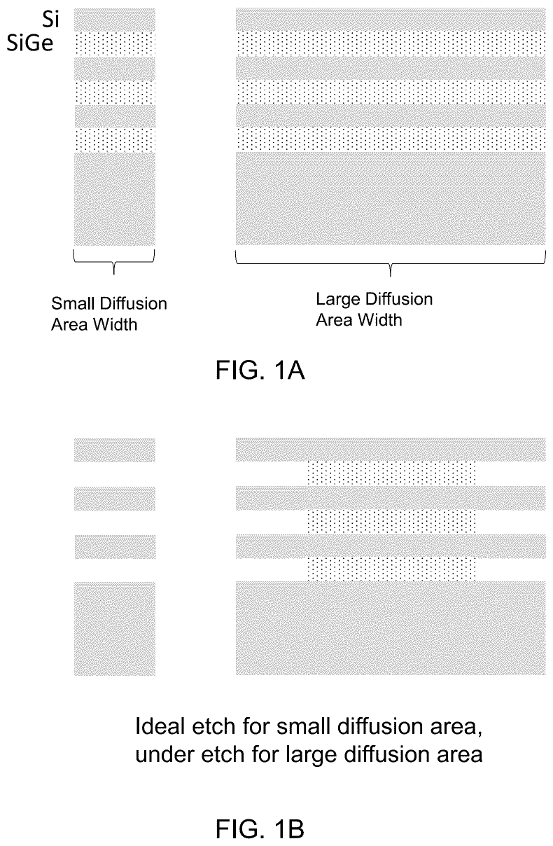

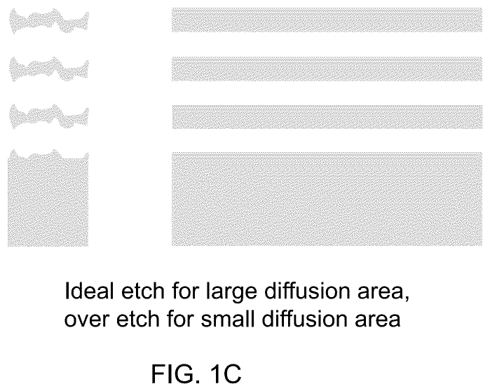

FIGS. 1A-1C illustrate cross-sectional views of a small width diffusion area and a large width diffusion area for a channel area of a nanosheet transistor structure related to a nanosheet release process. FIG. 1A illustrates cross-sectional views of the small width diffusion area and the large width diffusion area prior to etching. Nanosheet (NS) diffusion size is limited by etch selectivity of silicon (Si) to silicon germanium (SiGe) etch during nanosheet release. FIG. 1B illustrates cross-sectional views of the small width diffusion area and the large width diffusion area after etching for a channel areal, for an etching optimized for small widths. For etching optimized for small widths, the SiGe may be under etched for devices having large width diffusion areas. The large width diffusion area may be incompletely etched. FIG. 1C illustrates cross-sectional views of the small width diffusion area and the large width diffusion area after etching for a channel area, for an etching optimized for large widths. For etching optimized for large widths, the SiGe and Si may be over etched for devices having small width diffusion areas. The small width diffusion area may be over-etched resulting in reduced thickness and rough surfaces and thus degraded mobility. For example, after removing SiGe during the etching process of the channel area, the Si layers are “released” and hang in the air connected to the epi S/D portions. Then the gaps are filled with gate dielectric and metal to form the metal gates.

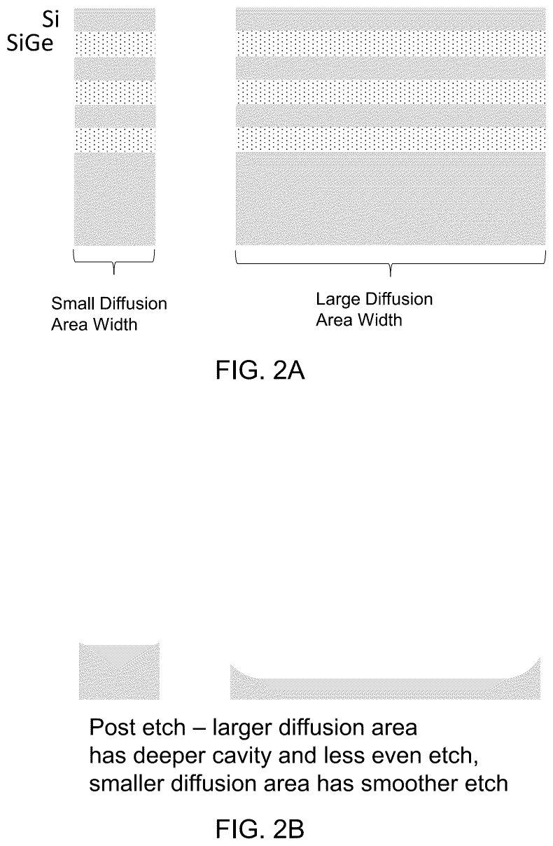

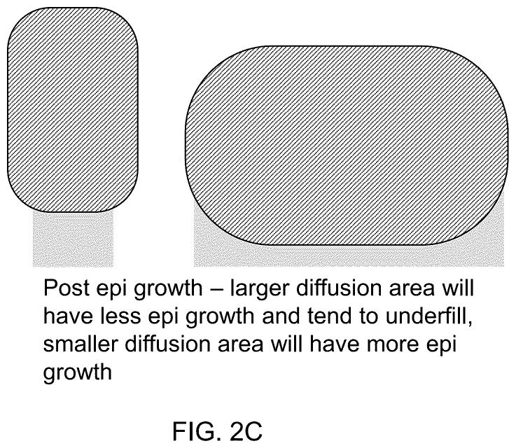

FIGS. 2A-2C illustrate cross-sectional views of a small width diffusion area and a large width diffusion area for a source and/or drain area of a nanosheet transistor structure related to a cavity etch and epitaxial layer growth process. FIG. 2A illustrates cross-sectional views of the small width diffusion area and the large width diffusion area prior to cavity etching and epitaxial growth of a diffusion area for a small width and a large width nanosheet transistor structure. Nanosheet diffusion size is also limited by cavity etch depth and epitaxial layer growth differences. FIG. 2B illustrates cross-sectional views of the small width diffusion area and the large width diffusion area after cavity etching for a source and/or drain area. For etching drain and source areas, the silicon (Si) of the larger width diffusion area may have a deeper cavity but the silicon (Si) may be not be evenly etched. FIG. 2C illustrates cross-sectional views of the small width diffusion area and the large width diffusion area after epitaxial layer growth for a source and/or drain area. For growing drain and source areas, the silicon (Si) of the larger width diffusion area may have less epitaxial layer growth and tend to be underfilled.

These problems are exacerbated in the fabrication of circuits with mixed height standard cells (i.e., where cells of different heights are included). Although these problems may be resolved with additional masking and process steps to separate NS release, cavity etch and epitaxial layer growth, such further processing increases cost and complexity with concomitant reduces yield.

Multi-height standard cells may have lower parasitic capacitance and provide much higher performance than adding additional legs with the minimum cell height standard cell because each additional leg introduces additional parasitic capacitances and reduces performance.

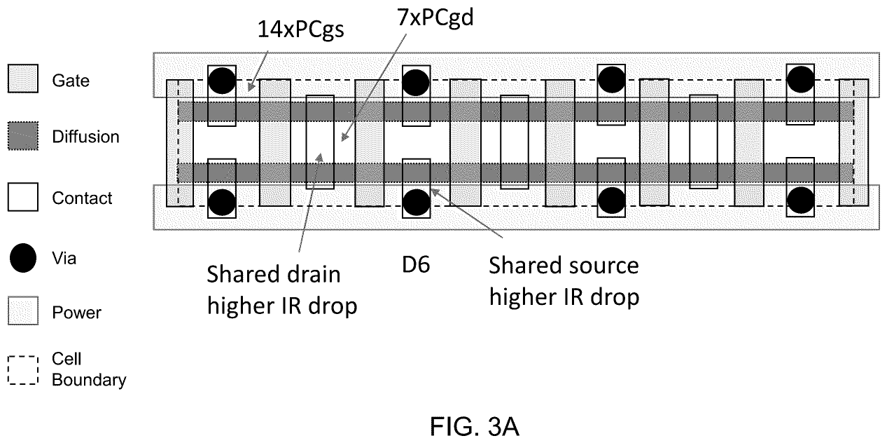

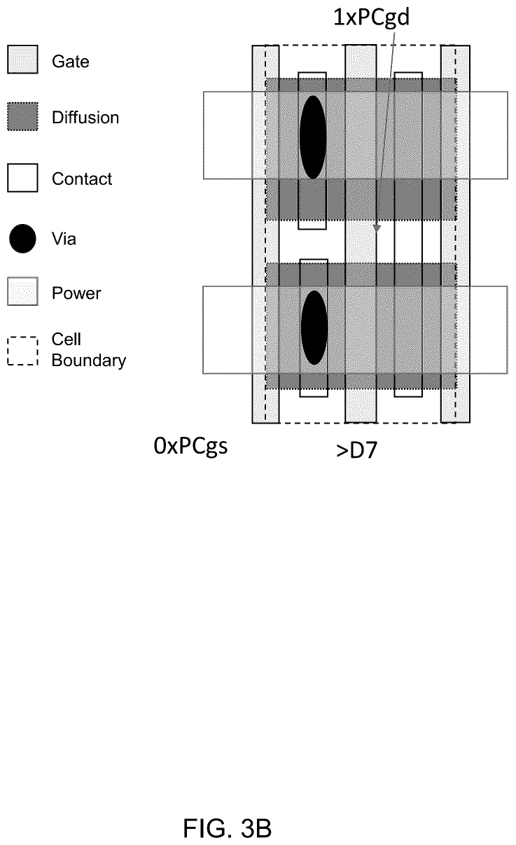

FIG. 3A is a schematic layout showing multiple inverter cells connected in parallel in a single row (e.g., minimum row height). For example, referring to FIG. 3A, there are 6 inverter cells connected in parallel to achieve a driving strength of 6 times the driving strength of a single inverter cell (e.g., D6). However, when connected in parallel, parasitic capacitance (PC) between each connection, e.g., gate-drain or gate-source, accumulates. Referring to FIG. 3A, parasitic capacitance arises from each of the 14 gate-source connections and each of the 7 gate-drain connections. Moreover, the shared drains and shared sources result in higher intermediate resistance (IR) drop. The layout has a footprint of 7CPP (cell poly pitch)×1CH (cell height).

FIG. 3B is a schematic layout showing a double row height inverter cell. For example, referring to FIG. 3B, the double row height inverter cell has a driving strength greater than seven times the driving strength of a single inverter cell based on total device width (e.g., D7). In general, multiples of a single row height can be stacked to form a multi-height cell having a large diffusion width with lower parasitic capacitances for the same drive (e.g., double, triple, quad, pent height). In a double height cell, for the same design rules as the schematic layout of FIG. 3A, a low parasitic capacitance double height cell layout can achieve a drive strength greater than 7 times that of a single row drive strength. It occupies a 2CPP (cell poly pitch)×2CH (cell height, 3CH if including empty space of half-row offset, due to clustering of half-row offset cells, the effective cell height will be between 2CH and 3CH) footprint and thus has a smaller area than the layout of FIG. 3A.

Multi-height standard cell layouts include different cell heights which are multiples of a base minimum cell height. A group of multiple NMOS diffusion areas and a group of multiple PMOS diffusion areas within the multi-cell heights. Alignment of power rails directly aligned over the multiple PMOS or NMOS diffusion areas.

This may apply to 2×, 3×, 4× and 5× standard cell heights. Maximizing the diffusion area size for NMOS and PMOS results in more efficient cells. The taller the cell, the larger the diffusion areas should be. However, as discussed above, the nanosheet diffusion size is limited by etch selectivity of silicon to silicon germanium during the nanosheet release etch. If the etch selectivity of silicon to silicon germanium is not perfect, or there is interdiffusion between the two, a longer etch is needed. A longer etch which completely clears the silicon germanium in the larger diffusion areas may result in silicon layers of the smaller diffusion areas to be too thin and have too rough of a surface. Similar issues exist at source and drain formation. For the same etching process, the larger diffusion areas are likely to have a deeper cavity as compared the smaller diffusion areas. Similarly, for the same epitaxial growth process, epitaxial growth in the larger diffusion areas is expected to be smaller than epitaxial growth in the smaller diffusion areas, resulting in higher resistance for the larger diffusion areas.

While these differences may be solved by additional masking and process steps to separate the cavity etch into multiple etches, epitaxial growth into multiple epitaxial growth steps, and nanosheet release into multiple steps, the additional processes increase cost and complexity and risk of yield reduction. A solution may be to divide the larger diffusion areas into multiple smaller diffusion areas occupying approximately the same footprint as the larger diffusion area. The single large diffusion area in multi-height cells may be divided into multiple diffusion areas. The spacing between the multiple diffusion areas may be equal to or greater than the minimum gate to diffusion extension length. The multiple diffusion areas for NMOS are connected by a common trench contact, as is the case for PMOS.

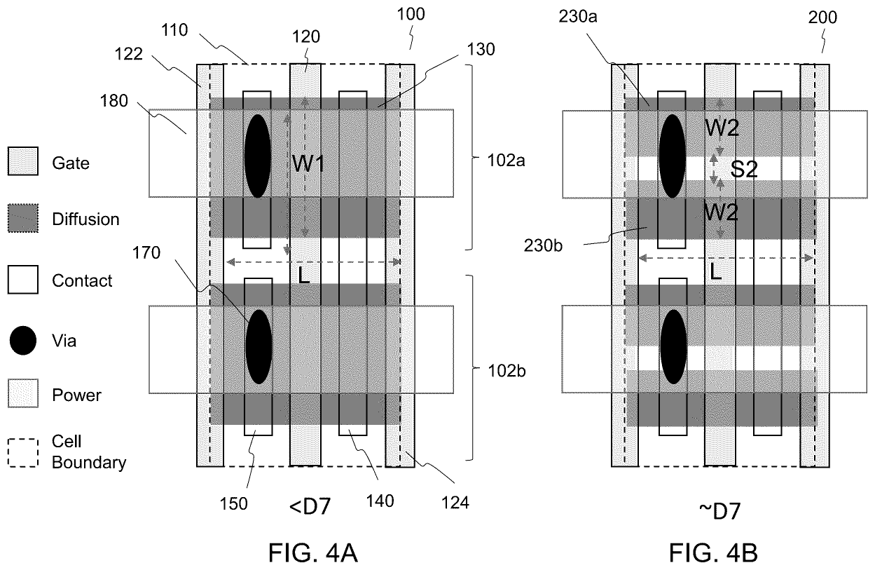

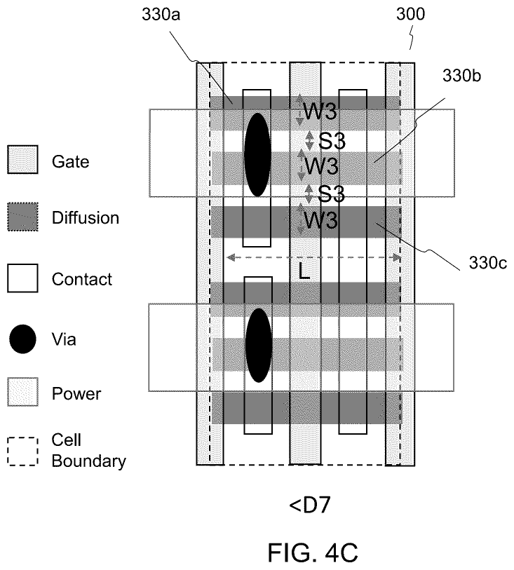

FIG. 4A is schematic layout showing a multi-height cell having large diffusion areas. FIG. 4A may be a schematic layout for a conventional multi-height cell 100 (e.g., the inverter cell of FIG. 3B). A multi-height cell 100 may include two single height cells 102a and 102b. The footprint of the multi-height cell is illustrated by the cell boundary 110. The two single height cells may be disposed to align in a vertical direction to form a multi-height cell. Each single height cell may include a diffusion area 130 have a width W1 and a length L. The width W1 extends along a vertical direction of the multi-height cell and the length L extends long a horizontal direction of the multi-height cell. A first gate (e.g., poly) 120 may be disposed to extend along a vertical direction over a central portion of the diffusion area 130 of both single height cells 102a and 102b. A second gate (e.g., poly) 122 may be disposed to extend along a vertical direction over a first end portion of the diffusion area 130 of both single height cells 102a and 102b. A third gate (e.g., poly) 124 may be disposed to extend along a vertical direction over a second end portion of the diffusion area 130 of both single height cells 102a and 102b. The first gate 120 may be an active gate. The second and third gates 122, 124 may be dummy gates. The gates may be continuous between the single height cells. A drain contact 140 may be disposed to extend along a vertical direction over the diffusion area 130 of both single height cells 102a and 102b between the first gate 120 and the third gate 124. The drain contact may be continuous between the single height cells. A source contact 150 may be disposed to extend along a vertical direction over the diffusion area 130 of each single height cells 102a and 102b between the first gate 120 and the second gate 122. The source contact 150 is discontinuous between each single height cell. For each single height cell, a power line 180 may be disposed to extend along a horizontal direction over the diffusion area 130 of a single height cell and a via 170 may be disposed to connect the power line 180 to the diffusion area 130. That is, the circuit of FIG. 4A may be a CMOS inverter where one single height cell 102a is a first type (e.g., N-type) and the other single height cell 102b is a second type (e.g., P-type) different that the first type. The gate 120 may be an input of the inverter circuit and the drain contact may be an output of the inverter circuit. The circuit of FIG. 4A may achieve a drive strength greater than 7 times the drive strength of a single height inverter cell.

FIGS. 4B-4C are schematic layouts showing a multi-height cell having multiple diffusion areas according to various non-limiting aspects described herein. For a given multi-height cell, the diffusion area can be broken into multiple smaller diffusion areas without significant loss of the drive current.

FIG. 4B is a schematic layout for a multi-height cell with two smaller diffusions areas according various aspects described herein. The multi-height cell of FIG. 4B may be the same as or similar to the multi-height cell of FIG. 4A, except the multi-height cell of FIG. 4B includes two smaller diffusion areas. Each diffusion area 230a and 230b may have a width W2 and a length L. The width W2 extends along a vertical direction of the multi-height cell and the length L extends long a horizontal direction of the multi-height cell. The diffusion areas are separated by a spacing S2. Spacing S2 extends along a vertical direction of the multi-height cell. The total area of the diffusion areas and diffusion spacing of the multi-height cell of FIG. 4B may be the same as or substantially the same as the diffusion area of the multi-height cell of FIG. 4A. That is, with respect to FIG. 4A, W2+S2+W2 may be the same as or substantially the same as W1. The circuit of FIG. 4B may achieve a drive strength of approximately 7 times the drive strength of a single height inverter cell. In non-limiting aspects, the two diffusion areas 230a and 230b may have substantially the same length and substantially the same width.

FIG. 4C is a schematic layout for a multi-height cell with three smaller diffusions areas according various aspects described herein. The multi-height cell of FIG. 4C may be the same as or similar to the multi-height cell of FIG. 4A, except the multi-height cell of FIG. 4C includes three smaller diffusion areas. Each diffusion area 330a, 330b and 330c may have a width W3 and a length L. The width W3 extends along a vertical direction of the multi-height cell and the length L extends long a horizontal direction of the multi-height cell. The diffusion areas are separated by a spacing S3. Spacing S3 extends along a vertical direction of the multi-height cell. The total area of the diffusion areas and diffusion spacings of the multi-height cell of FIG. 4C may be the same as or substantially the same as the diffusion area of the multi-height cell of FIG. 4A. That is, with respect to FIG. 4A, W3+S3+W3+S3+W3 may be the same as or substantially the same as W1. The circuit of FIG. 4C may achieve a drive strength less than 7 times the drive strength of a single height inverter cell. In non-limiting aspects, the three diffusion areas 330a, 330b and 330c may have substantially the same length and substantially the same width.

Referring to FIGS. 4A-4C, W1=W2+S2+W2=W3+S3+W3+S3+W3. The benefits of further reducing the diffusion areas. These multiple diffusion areas are connected by common source/drain contacts, so they are devices in parallel.

Conventional multi-height cells include standard cell patterns stacked on top of each other. For example, a conventional multi-height cell may have PNNPPN for a triple height cell in terms of device types. That is, it is similar to stacking 3 PN cells on top of each other with mirroring at the boundary. As described herein, a triple height cell is one large PN (large diffusion areas) or PPNN (separated into 2 diffusions per device polarity), or PPPNNN (separated into 3 diffusions per device polarity), PPPNN (separated into 3 diffusions per one device polarity and 2 diffusions per another device polarity), etc.

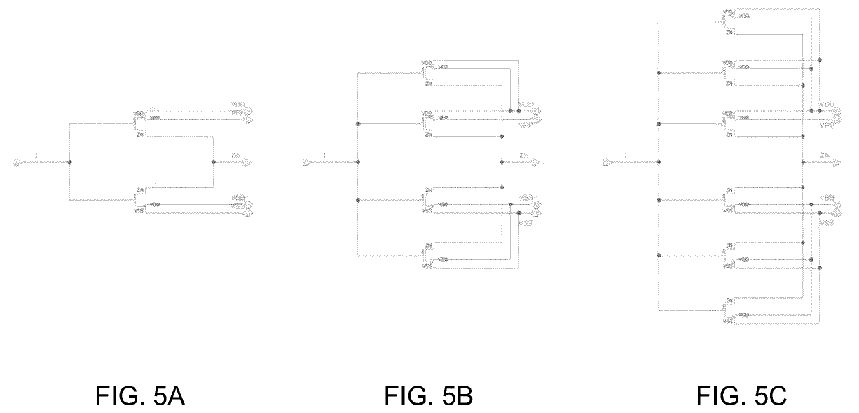

FIGS. 5A-5C are schematic diagrams showing equivalent circuits corresponding to the schematic layouts of FIGS. 4A-4C, respectively. As shown in FIG. 5A, the circuit of FIG. 4A is a conventional inverter circuit having a first transistor of a first type and a second transistor of a second type connected to each other at their drains. As shown in FIG. 5B, the circuit of FIG. 4B is an inverter circuit having two transistors of a first type connected in parallel between power (e.g., Vdd) and drain and two transistors of a second type connected in parallel between power (e.g., Vss) and drain and all four transistors connected to each other at their drains. As shown in FIG. 5C, the circuit of FIG. 4C is an inverter circuit having three transistors of a first type connected in parallel between power (e.g., Vdd) and drain and three transistors of a second type connected in parallel between power (e.g., Vss) and drain and all six transistors connected to each other at their drains.

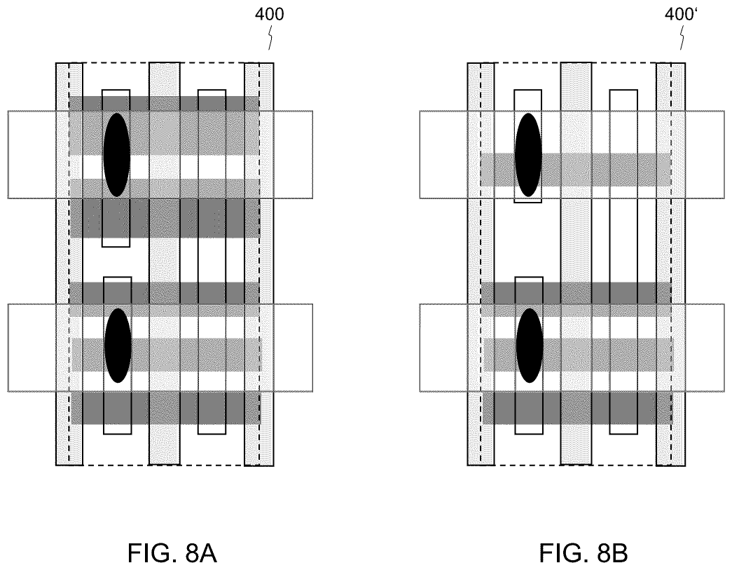

The number of diffusion areas within a particular multi-height cell can vary between NMOS and PMOS. For example, NMOS may have 2 diffusion areas whereas PMOS may have 3 diffusion areas. FIG. 8A is a schematic layout showing a multi-height cell having a different number of diffusion areas according to various non-limiting aspects described herein. The choice depends on how the devices behave as a function of performance versus diffusion width, as well as the space between the diffusion areas based on the process capability of the fabrication technology to dope and fill the metal gate sufficiently to achieve the proper metal work function. The space between the diffusion areas determines the tradeoff between the loss of effective width of a single large diffusion area divided into multiple smaller diffusion areas, versus the increased performance of multiple smaller individual diffusion areas as a whole versus one large diffusion area. This is detailed in the following illustrations.

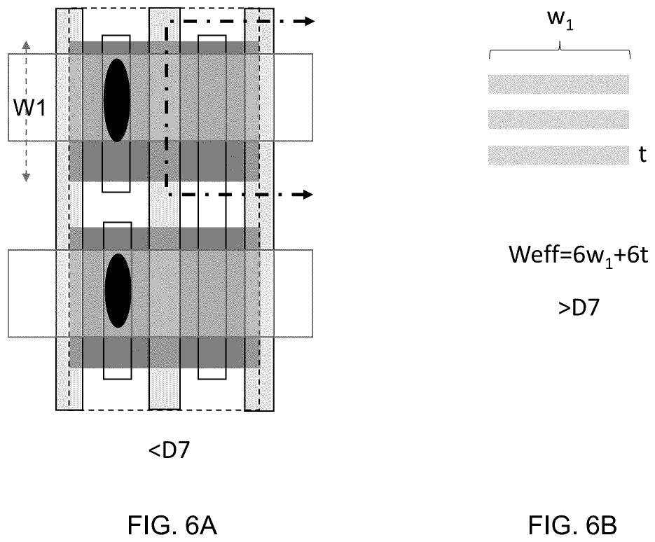

FIG. 6A is a schematic layout showing a multi-height cell having a single diffusion area. For example, the circuit of FIG. 6A may be the same or similar to the circuit of FIG. 4A. FIG. 6B is a cross-sectional view of the diffusion area thereof. W_{eff}=6w₁+6t and a drive strength greater than 7 times the driving strength of a single inverter.

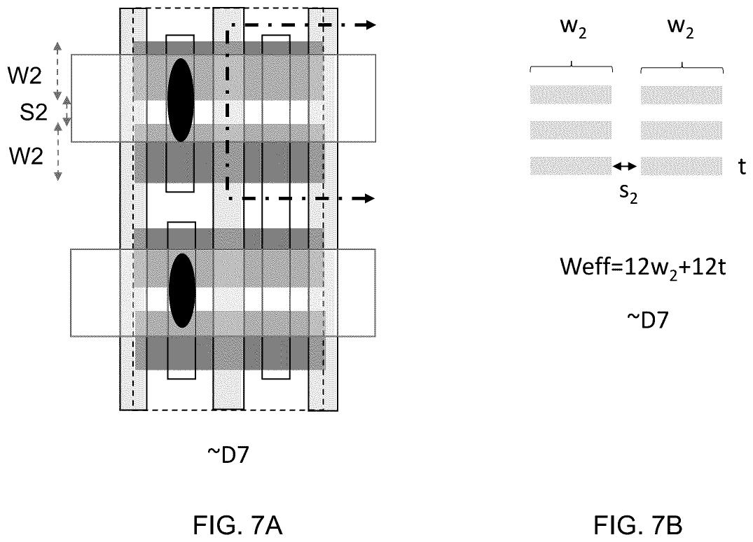

FIG. 7A is a schematic layout showing a multi-height cell having a two diffusion areas according to various non-limiting aspects described herein. For example, the circuit of FIG. 7A may be the same or similar to the circuit of FIG. 4B. FIG. 7B is a cross-sectional view of the diffusion areas thereof. W_{eff}=12w₂+12t and a drive strength of approximately 7 times the driving strength of a single inverter. Referring to FIG. 7B, each of the two diffusion areas has a width w₂ and are separated by a spacing s₂. Each of the two diffusion areas comprises a plurality of silicon layers of thickness t. The width of the diffusion areas w₂ should be greater than the spacing s₂ between the diffusion areas. The spacing s₂ between the diffusion areas should be greater than the thickness t of a silicon layer. The spacing s₂ between the diffusion areas may be approximately 2 times the thickness t of a silicon layer.

Sheet space is determined by the process capability to dope and fill the metal gate sufficiently to achieve the proper work function. The effective device width is not reduced if a width s of the space between diffusion areas is approximately the same as a thickness t of a silicon layer (e.g., s=t). Typically, the width s between the diffusion areas may be approximately 2 times the thickness t of the silicon layer (e.g., ˜2t), so there is some reduction in the total device effective width. Nevertheless, due to better epitaxial cavity etch and fill in smaller diffusion areas, multiple smaller diffusion area width devices are stronger than a single large diffusion width device when comparing the same or similar overall diffusion area footprint (e.g., W1=W2+S2+W2=W3+S3 +W3+S3+W3), so there is a net advantage in drive current at a lower capacitance due to smaller effective diffusion size. The benefits of the smaller diffusion areas decreases as the diffusion area width approaches the width of the space between the diffusion areas. That is, the width s of the space between the diffusion areas should be less than a width w of the diffusion areas. When the width s is greater than the width w, efficiency decreases because each space between the diffusion areas introduces parasitic capacitance.

FIG. 8B shows a configuration where the multiple diffusions for a given device may be depopulated to skew the ratio of devices or to achieve a particular drive current so that there may be fewer than the maximum number of diffusions, in any combination, for example 1 NMOS vs. 3 PMOS. Note the contact length would scale.

Although dividing one large diffusion area into multiple smaller diffusion areas is shown with respect to an inverter cell, the advantages of this aspect may be applicable to various other functional cells (e.g., other boolean logic cells, adders, flip-flops, etc).

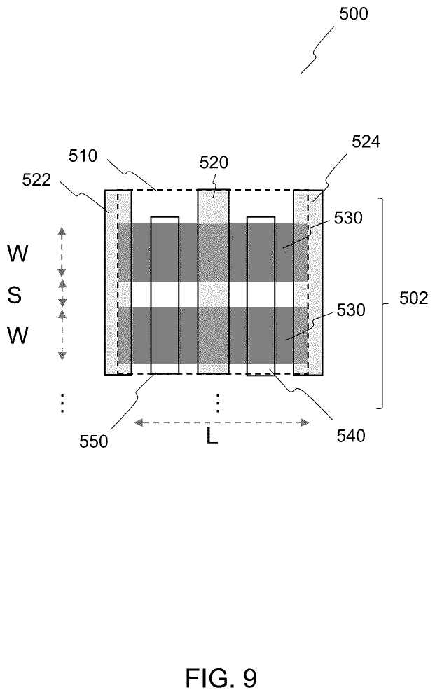

FIG. 9 is schematic layout showing a portion of a multi-height cell 500 having multiple diffusion areas according to various non-limiting aspects described herein. A multi-height cell 500 may have a cell height that is a multiple of a single height cell. A multi-height cell may have two portions 502, e.g., an NMOS portion (e.g., only one stripe of NMOS) and a PMOS portion (e.g., only one stripe of PMOS). Only one portion 502 is shown in FIG. 9. A portion 502 may include one or more diffusion areas 530 having a width W and a length L. In some non-limiting aspects, the one or more diffusion areas 530 may include 2 or 3 diffusion areas. The width W extends along a vertical direction of a multi-height cell which is the same as a vertical direction of a single height cell and the length L extends along a horizontal direction of a multi-height cell which is the same as a horizontal direction of the single height cell. The plurality of diffusion areas 530 are separated by a spacing S between every two adjacent diffusion areas of the plurality of diffusion areas. Spacing S extends along a vertical direction of the multi-height cell. A first gate (e.g., poly) 520 may be disposed to extend along a vertical direction over a central portion of the plurality of diffusion areas 530 of portion 502. A second gate (e.g., poly) 522 may be disposed to extend along a vertical direction over a first end portion of the plurality of diffusion areas 530 of portion 502. A third gate (e.g., poly) 524 may be disposed to extend along a vertical direction over a second end portion of the plurality of diffusion areas 530 of portion 502. The first gate 520 may be an active gate. The second and third gates 522, 524 may be dummy gates. The gates are continuous among the plurality of diffusion areas 530 of portion 502. A drain contact 540 may be disposed to extend along a vertical direction over the plurality of diffusion areas 530 of portion 502 between the first gate 520 and the third gate 524. The drain contact is continuous among the plurality of diffusion areas 530 of portion 502. A source contact 550 may be disposed to extend along a vertical direction over the plurality of diffusion areas 530 of portion 502 between the first gate 520 and the second gate 522. The source contact 550 is continuous among the plurality of diffusion areas 530 of portion 502.

Example 1 may be a device comprising: a multi-height cell comprising: a plurality of diffusion areas, each diffusion area having a substantially same length that extends along a horizontal direction of the multi-height cell, every two adjacent diffusion areas of the plurality of diffusion areas separated by a spacing, wherein the spacing extends along in a vertical direction of the multi-height cell; a gate disposed continuously over a central portion of the plurality of diffusion areas, the gate extends along in the vertical direction of the multi-height cell; a source contact disposed continuously over a first portion of the plurality of diffusion areas, the source contact extends along in the vertical direction of the multi-height cell; and a drain contact disposed continuously over a second portion of the plurality of diffusion areas, the drain contact extends along in the vertical direction of the multi-height cell.

Example 2 may be the device of Example 1, wherein each diffusion area has a width that extends along the vertical direction of the multi-height cell and the width of each diffusion area is greater than the spacing between the every two adjacent diffusion areas.

Example 3 may be the device of Example 2, wherein the width of each diffusion area is substantially the same.

Example 4 may be the device of any one of Examples 1-3, wherein the plurality of diffusion areas comprises two or three diffusion areas.

Example 5 may be the device of any one of Examples 1-4, each of the plurality of diffusion areas comprises a plurality of silicon layers.

Example 6 may be the device of Example 5, wherein a silicon layer of the plurality of silicon layers has a thickness, wherein the spacing is greater than the thickness of the silicon layer.

Example 7 may be the device of Example 6, wherein the spacing is approximately two times the thickness of the silicon layer.

Example 8 may be the device of any one of Examples 1-7, further comprising: a plurality of second diffusion areas, each second diffusion area having a same length that extends along the horizontal direction of the multi-height cell, every two adjacent second diffusion areas of the plurality of second diffusion areas separated by a second spacing, wherein the second spacing extends along in the vertical direction of the multi-height cell.

Example 9 may be the device of Example 8, wherein a number of the plurality of diffusion areas is the same as a number of the plurality of second diffusion areas.

Example 10 may be the device of Example 8, wherein a number of the plurality of diffusion areas is different than a number of the plurality of second diffusion areas.

Example 11 may be the device of any one of Examples 8-10, wherein the plurality of diffusion areas and the plurality of second diffusion areas are disposed adjacent to each other in the vertical direction of the multi-height cell circuit.

Example 12 may be the device of Example 11, further comprising: a second gate disposed continuously over a central portion of the plurality of second diffusion areas, the second gate extends along in the vertical direction of the multi-height cell; a second source contact disposed continuously over a first portion of the plurality of second diffusion areas, the second source contact extends along in the vertical direction of the multi-height cell; and a second drain contact disposed continuously over a second portion of the plurality of second diffusion areas, the second drain contact extends along in the vertical direction of the multi-height cell.

Example 13 may be the device of Example 12, wherein the plurality of diffusion areas comprises a first conductivity type and the plurality of second diffusion areas comprises a second conductivity type different than the first conductivity type.

Example 14 may be the device of any one of Examples 12-13, wherein the gate and the second gate comprises a continuous poly extending across the plurality of diffusion areas and the plurality of second diffusion areas.

Example 15 may be the device of any one of Examples 12-14, wherein the drain contact and the second drain contact comprises a continuous metal extending across the plurality of diffusion areas and the plurality of second diffusion areas.

Example 16 may be the device of any one of Examples 12-15, wherein the multi-height cell further comprises a first power line electrically connected to the source contact and wherein the second cell further comprises a second power line electrically connected to the second source contact.

Example 17 may be the device of any one of Examples 12-16, wherein the plurality of diffusion areas are connected in parallel between source contact and the drain contact and wherein the plurality of second diffusion areas are connected in parallel between the second source contact and the second drain contact.

Example 18 may be a device comprising: a multi-height cell comprising: one or more diffusion areas, each diffusion area having a substantially same length that extends along a horizontal direction of the multi-height cell, every two adjacent diffusion areas of the one or more diffusion areas separated by a spacing, wherein the spacing extends along in a vertical direction of the multi-height cell; a gate disposed continuously over a central portion of the one or more diffusion areas, the gate extends along in the vertical direction of the multi-height cell; a source contact disposed continuously over a first portion of the one or more diffusion areas, the source contact extends along in the vertical direction of the multi-height cell; and a drain contact disposed continuously over a second portion of the one or more diffusion areas, the drain contact extends along in the vertical direction of the multi-height cell.

Example 19 may be the device of Example 18, further comprising: one or more second diffusion areas, each second diffusion area having a same length that extends along the horizontal direction of the multi-height cell, every two adjacent second diffusion areas of the one or more second diffusion areas separated by a second spacing, wherein the second spacing extends along in the vertical direction of the multi-height cell.

Example 20 may be the device of Example 19, further comprising: a second gate disposed continuously over a central portion of the one or more second diffusion areas, the second gate extends along in the vertical direction of the multi-height cell; a second source contact disposed continuously over a first portion of the one or more second diffusion areas, the second source contact extends along in the vertical direction of the multi-height cell; and a second drain contact disposed continuously over a second portion of the one or more second diffusion areas, the second drain contact extends along in the vertical direction of the multi-height cell.

Example 21 may be the device of any one of Examples 18-20, wherein each diffusion area has a width that extends along the vertical direction of the multi-height cell and the width of each diffusion area is greater than the spacing between the every two adjacent diffusion areas.

Example 22 may be the device of Example 21, wherein the width of each diffusion areas is substantially the same.

Example 23 may be the device of any one of Examples 18-22, wherein the one or more diffusion areas comprises two or three diffusion areas.

Example 24 may be the device of any one of Examples 18-23, each of the one or more diffusion areas comprises a plurality of silicon layers.

Example 25 may be the device of Example 24, wherein a silicon layer of the plurality of silicon layers has a thickness, wherein the spacing is greater than the thickness of the silicon layer.

Example 26 may be the device of Example 25, wherein the spacing is approximately two times the thickness of the silicon layer.

Example 27 may be the device of any one of Examples 19-26, wherein a number of the one or more diffusion areas is the same as a number of the one or more second diffusion areas.

Example 28 may be the device of any one of Examples 19-26, wherein a number of the one or more diffusion areas is different than a number of the one or more second diffusion areas.

Example 29 may be the device of any one of Examples 19-26, wherein the one or more diffusion areas and the one or more second diffusion areas are disposed adjacent to each other in the vertical direction of the multi-height cell circuit.

Example 30 may be the device of any one of Examples 19-29, wherein the one or more diffusion areas comprises a first conductivity type and the plurality of second diffusion areas comprises a second conductivity type different than the first conductivity type.

Example 31 may be the device of any one of Examples 19-30, wherein the gate and the second gate comprises a continuous poly extending across the plurality of diffusion areas and the plurality of second diffusion areas.

Example 32 may be the device of any one of Examples 19-31, wherein the drain contact and the second drain contact comprises a continuous metal extending across the plurality of diffusion areas and the plurality of second diffusion areas.

Example 33 may be the device of any one of Examples 19-32, wherein the multi-height cell further comprises a first power line electrically connected to the source contact and wherein the second cell further comprises a second power line electrically connected to the second source contact.

Example 34 may be the device of any one of Examples 19-33, wherein the plurality of diffusion areas are connected in parallel between source contact and the drain contact and wherein the plurality of second diffusion areas are connected in parallel between the second source contact and the second drain contact.

Example 35 may be a method comprising: providing a multi-height cell; providing a plurality of diffusion areas, each diffusion area having a substantially same length that extends along a horizontal direction of the multi-height cell, every two adjacent diffusion areas of the plurality of diffusion areas separated by a spacing, wherein the spacing extends along in a vertical direction of the multi-height cell; providing a gate disposed continuously over a central portion of the plurality of diffusion areas, the gate extends along in the vertical direction of the multi-height cell; providing a source contact disposed continuously over a first portion of the plurality of diffusion areas, the source contact extends along in the vertical direction of the multi-height cell; and providing a drain contact disposed continuously over a second portion of the plurality of diffusion areas, the drain contact extends along in the vertical direction of the multi-height cell.

Example 36 may be the method of Example 35, wherein each diffusion area has a width that extends along the vertical direction of the multi-height cell and the width of each diffusion area is greater than the spacing between the every two adjacent diffusion areas.

Example 37 may be the method of Example 36, wherein the width of each diffusion area is substantially the same.

Example 38 may be the method of any one of Examples 35-37, wherein the plurality of diffusion areas comprises two or three diffusion areas.

Example 39 may be the method of any one of Examples 35-38, each of the plurality of diffusion areas comprises a plurality of silicon layers.

Example 40 may be the method of Example 39, wherein a silicon layer of the plurality of silicon layers has a thickness, wherein the spacing is greater than the thickness of the silicon layer.

Example 41 may be the method of Example 40, wherein the spacing is approximately two times the thickness of the silicon layer.

Example 42 may be the method of any one of Examples 35-41, further comprising: providing a plurality of second diffusion areas, each second diffusion area having a same length that extends along the horizontal direction of the multi-height cell, every two adjacent second diffusion areas of the plurality of second diffusion areas separated by a second spacing, wherein the second spacing extends along in the vertical direction of the multi-height cell.

Example 43 may be the method of Example 42, wherein a number of the plurality of diffusion areas is the same as a number of the plurality of second diffusion areas.

Example 44 may be the method of Example 42, wherein a number of the plurality of diffusion areas is different than a number of the plurality of second diffusion areas.

Example 45 may be the method of any one of Examples 42-44, wherein the plurality of diffusion areas and the plurality of second diffusion areas are disposed adjacent to each other in the vertical direction of the multi-height cell circuit.

Example 46 may be the method of Example 45, further comprising: providing a second gate disposed continuously over a central portion of the plurality of second diffusion areas, the second gate extends along in the vertical direction of the multi-height cell; providing a second source contact disposed continuously over a first portion of the plurality of second diffusion areas, the second source contact extends along in the vertical direction of the multi-height cell; and providing a second drain contact disposed continuously over a second portion of the plurality of second diffusion areas, the second drain contact extends along in the vertical direction of the multi-height cell.

Example 47 may be the method of Example 46, wherein the plurality of diffusion areas comprises a first conductivity type and the plurality of second diffusion areas comprises a second conductivity type different than the first conductivity type.

Example 48 may be the method of any one of Examples 45-47, wherein the gate and the second gate comprises a continuous poly extending across the plurality of diffusion areas and the plurality of second diffusion areas.

Example 48 may be the method of any one of Examples 45-47, wherein the drain contact and the second drain contact comprises a continuous metal extending across the plurality of diffusion areas and the plurality of second diffusion areas.

Example 49 may be the method of any one of Examples 45-48, wherein the multi-height cell further comprises a first power line electrically connected to the source contact and wherein the second cell further comprises a second power line electrically connected to the second source contact.

Example 50 may be the device of any one of Examples 45-49, wherein the plurality of diffusion areas are connected in parallel between source contact and the drain contact and wherein the plurality of second diffusion areas are connected in parallel between the second source contact and the second drain contact.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products. p A number of aspects have been described. Nevertheless, it will be understood that various modifications can be made. Accordingly, other aspects are within the scope of the following claims.

What is claimed:

1. A device comprising:
a multi-height cell comprising:
a plurality of diffusion areas, each diffusion area having a substantially same length that extends along a horizontal direction of the multi-height cell, every two adjacent diffusion areas of the plurality of diffusion areas separated by a spacing, wherein the spacing extends along in a vertical direction of the multi-height cell;
a gate disposed continuously over a central portion of the plurality of diffusion areas, the gate extends along in the vertical direction of the multi-height cell;
a source contact disposed continuously over a first portion of the plurality of diffusion areas, the source contact extends along in the vertical direction of the multi-height cell; and
a drain contact disposed continuously over a second portion of the plurality of diffusion areas, the drain contact extends along in the vertical direction of the multi-height cell.

2. The device of claim 1, wherein each diffusion area has a width that extends along the vertical direction of the multi-height cell and the width of each diffusion area is greater than the spacing between the every two adjacent diffusion areas.

3. The device of claim 2, wherein the width of each diffusion area is substantially the same.

4. The device of claim 2, wherein the plurality of diffusion areas comprises two or three diffusion areas.

5. The device of claim 1, each of the plurality of diffusion areas comprises a plurality of silicon layers.

6. The device of claim 5, wherein a silicon layer of the plurality of silicon layers has a thickness, wherein the spacing is greater than the thickness of the silicon layer.

7. The device of claim 6, wherein the spacing is approximately two times the thickness of the silicon layer.

8. The device of claim 1, further comprises:
a plurality of second diffusion areas, each second diffusion area having a same length that extends along the horizontal direction of the multi-height cell, every two adjacent second diffusion areas of the plurality of second diffusion areas separated by a second spacing, wherein the second spacing extends along in the vertical direction of the multi-height cell.

9. The device of claim 8, wherein the plurality of diffusion areas and the plurality of second diffusion areas are disposed adjacent to each other in the vertical direction of the multi-height cell circuit.

10. The device of claim 9, further comprises:
a second gate disposed continuously over a central portion of the plurality of second diffusion areas, the second gate extends along in the vertical direction of the multi-height cell;
a second source contact disposed continuously over a first portion of the plurality of second diffusion areas, the second source contact extends along in the vertical direction of the multi-height cell; and
a second drain contact disposed continuously over a second portion of the plurality of second diffusion areas, the second drain contact extends along in the vertical direction of the multi-height cell.

11. The device of claim 10, wherein the plurality of diffusion areas comprises a first conductivity type and the plurality of second diffusion areas comprises a second conductivity type different than the first conductivity type.

12. The device of claim 11, wherein the gate and the second gate comprise a continuous poly extending across the plurality of diffusion areas and the plurality of second diffusion areas.

13. The device of claim 11, wherein the drain contact and the second drain contact comprise a continuous metal extending across the plurality of diffusion areas and the plurality of second diffusion areas.

14. The device of claim 11, wherein the multi-height cell further comprises a first power line electrically connected to the source contact and wherein the second cell further comprises a second power line electrically connected to the second source contact.

15. The device of claim 11, wherein the plurality of diffusion areas are connected in parallel between source contact and the drain contact and wherein the plurality of second diffusion areas are connected in parallel between the second source contact and the second drain contact.

16. A device comprising:
a multi-height cell comprising:
one or more diffusion areas, each diffusion area having a same length that extends along a horizontal direction of the multi-height cell, every two adjacent diffusion areas of the one or more diffusion areas separated by a spacing, wherein the spacing extends along in a vertical direction of the multi-height cell;
a gate disposed continuously over a central portion of the one or more diffusion areas, the gate extends along in the vertical direction of the multi-height cell;
a source contact disposed continuously over a first portion of the one or more diffusion areas, the source contact extends along in the vertical direction of the multi-height cell; and
a drain contact disposed continuously over a second portion of the one or more diffusion areas, the drain contact extends along in the vertical direction of the multi-height cell.

17. The device of 16, further comprises:
one or more second diffusion areas, each second diffusion area having a same length that extends along the horizontal direction of the multi-height cell, every two adjacent second diffusion areas of the one or more second diffusion areas separated by a second spacing, wherein the second spacing extends along in the vertical direction of the multi-height cell.

18. The device of claim 17, further comprises:
a second gate disposed continuously over a central portion of the one or more second diffusion areas, the second gate extends along in the vertical direction of the multi-height cell;
a second source contact disposed continuously over a first portion of the one or more second diffusion areas, the second source contact extends along in the vertical direction of the multi-height cell; and
a second drain contact disposed continuously over a second portion of the one or more second diffusion areas, the second drain contact extends along in the vertical direction of the multi-height cell.

19. A method, comprising:
providing a multi-height cell;
providing a plurality of diffusion areas, each diffusion area having a substantially same length that extends along a horizontal direction of the multi-height cell, every two adjacent diffusion areas of the plurality of diffusion areas separated by a spacing, wherein the spacing extends along in a vertical direction of the multi-height cell;
providing a gate disposed continuously over a central portion of the plurality of diffusion areas, the gate extends along in the vertical direction of the multi-height cell;
providing a source contact disposed continuously over a first portion of the plurality of diffusion areas, the source contact extends along in the vertical direction of the multi-height cell; and
providing a drain contact disposed continuously over a second portion of the plurality of diffusion areas, the drain contact extends along in the vertical direction of the multi-height cell.

20. The method of claim 19, further comprising:
providing one or more second diffusion areas, each second diffusion area having a same length that extends along the horizontal direction of the multi-height cell, every two adjacent second diffusion areas of the one or more second diffusion areas separated by a second spacing, wherein the second spacing extends along in the vertical direction of the multi-height cell.
